(19) United States
(12) Patent Application Publication
(10) Pub. No.: US 2026/0324472 A1
(43) Pub. Date: Oct. 15, 2026

(54) SEMICONDUCTOR PACKAGE INCLUDING NOISE REDUCING STRUCTURE

(71) Applicant: Samsung Electronics Co., Ltd., Suwon-si (KR)

(72) Inventors: Kwangjin Lee, Suwon-si (KR); Hyunjong Moon, Suwon-si (KR); Hyojung Ko, Suwon-si (KR); Inho Choi, Suwon-si (KR)

(21) Appl. No.: 19/424,995

(22) Filed: Dec. 18, 2025

(30) Foreign Application Priority Data
Apr. 11, 2025 (KR) 10-2025-0047683

(51) Int. Cl. H10W 70/654; H10W 70/60; H10W 70/685; H10W 90/00; H10W 90/10; H10B 80/00; H10D 80/30; H10W 72/00; H10W 74/10; H10W 90/24

(52) U.S. Cl. CPC H10W 70/654; H10W 70/611; H10W 70/687; H10W 90/10; H10W 90/754; H10B 80/00; H10D 80/30; H10W 72/877; H10W 74/117; H10W 90/24; H10W 90/734

(57) ABSTRACT

A semiconductor package includes a substrate, and a control chip and a memory chip provided on an upper surface of the substrate. The substrate includes an insulating pattern, and a connection pattern provided on an upper surface of the insulating pattern. The connection pattern electrically connects the control chip and the memory chip, and on a plan view, the connection pattern overlaps a lower surface of the control chip and a lower surface of the memory chip.

### CROSS-REFERENCE TO RELATED APPLICATIONS

This U.S. non-provisional patent application claims priority under 35 U.S.C. § 119 of Korean Patent Application No. 10-2025-0047683, filed on Apr. 11, 2025, the entire contents of which are hereby incorporated by reference.

### BACKGROUND

With development of the electronics industry, demand for high-functionality, high-speed, high-capacity and miniaturization of an electronic component is increasing. In response to this trend, a packaging technology has been developed to mount a plurality of semiconductor chips in a package.

A semiconductor package is an integrated circuit chip implemented in a form suitable for using in an electronic product. In general, the semiconductor package is manufactured by mounting the semiconductor chip on a print circuit board (PCB), and electrically connecting the same by using a bonding wire or bump. Semiconductor packages are being developed for miniaturization, weight reduction, and reduction of manufacturing cost. In order to perform miniaturization and weight reduction of such electronic components, it is desired to reduce the size of an individually-mounted component and integrate multiple separate elements into a package.

### SUMMARY

As semiconductor packaging technology expands to accommodate large-capacity storage means, or the like, various types of semiconductor packages have been introduced. However, an electromagnetic wave or the like emitted from a semiconductor chip within the package or transmitted from outside the semiconductor chip may generate noise in electrical signals within the semiconductor chip, which may cause malfunctions in the operation of the semiconductor chips. In addition, an electromagnetic interference phenomenon may occur between the semiconductor package and another electronic element.

The present disclosure provides a semiconductor package with improved electrical characteristics, and a method for manufacturing the same.

The present disclosure also provides a semiconductor package having a smaller size.

A technical goal of the disclosure is not limited to the goal mentioned above, and other technical goals that are not mentioned may be clearly understood from description below by those skilled in the art.

An implementation of the disclosure provides a semiconductor package including a substrate, and a control chip and a memory chip provided on an upper surface of the substrate, wherein the substrate includes an insulating pattern, and a connection pattern provided on an upper surface of the insulating pattern, the connection pattern electrically connects the control chip and the memory chip, and on a plan view, the connection pattern overlaps a lower surface of the control chip and a lower surface of the memory chip.

In an implementation of the disclosure, a semiconductor package includes a substrate including at least two relining layers, a control chip provided on an upper surface of the substrate, and a memory chip horizontally spaced apart from the control chip on the upper surface of the substrate, wherein an uppermost relining layer of the relining layers includes an insulating pattern, and a connection pattern provided on an upper surface of the insulating pattern, the control chip includes a first side surface and a second side surface opposed to each other, the memory chip includes a third side surface and a fourth side surface opposed to each other, the connection pattern connects the control chip and the memory chip, and on a plan view, the connection pattern crosses the first side surface, the second side surface, the third side surface and the fourth side surface.

In an implementation of the disclosure, a semiconductor package includes a substrate including at least two relining layers vertically stacked, a control chip provided on an upper surface of the substrate, a memory chip horizontally spaced apart from the control chip on the upper surface of the substrate, an external connection terminal provided on a lower surface of the substrate, a control chip wire connecting the control chip and the substrate, and a memory chip wire connecting the memory chip and the substrate, wherein an uppermost relining layer of the relining layers includes an insulating pattern, and a connection pattern electrically connecting the control chip and the memory chip on an upper surface of the insulating pattern, the control chip includes a first side surface and a second side surface opposed to each other, the memory chip includes a third side surface facing the first side surface and a fourth side surface opposed to the third side surface, the control chip wire is connected to one end of the connection pattern on the second side surface, the memory chip wire is connected to the other end of the connection pattern on the fourth side surface, and the connection pattern extends from the one end of the connection pattern to the other end of the connection pattern.

### BRIEF DESCRIPTION OF THE DRAWINGS

The accompanying drawings are included to provide a further understanding of the disclosure, and are incorporated in and constitute a part of this specification. The drawings illustrate implementations of the disclosure and, together with the description, serve to explain principles of the disclosure. In the drawings:

FIG. 1 is a plan view illustrating a semiconductor package according to implementations of the disclosure;

FIG. 2 is a cross-sectional view, taken along line A-A' of FIG. 1, illustrating a semiconductor package according to implementations of the disclosure;

FIGS. 3, 4, 5, 6, and 7 are cross-sectional views of a semiconductor package according to implementations of the disclosure; and

FIGS. 8 and 9 are cross-sectional views for describing a method for manufacturing a semiconductor package according to implementations of the disclosure.

### DETAILED DESCRIPTION

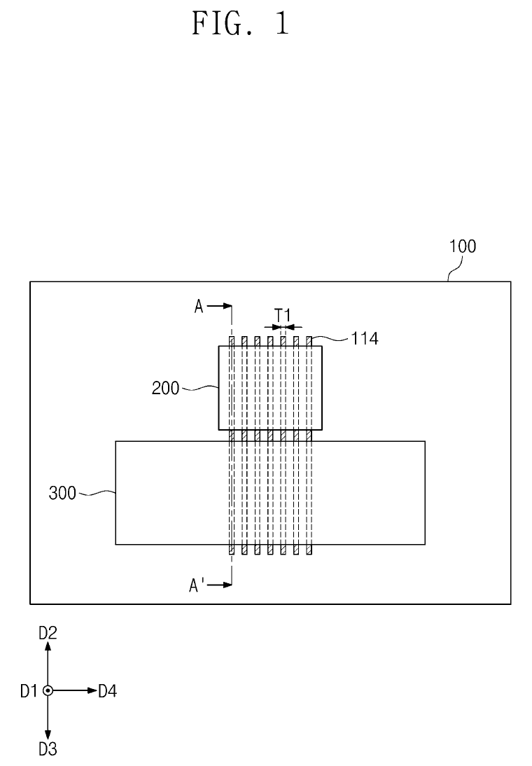

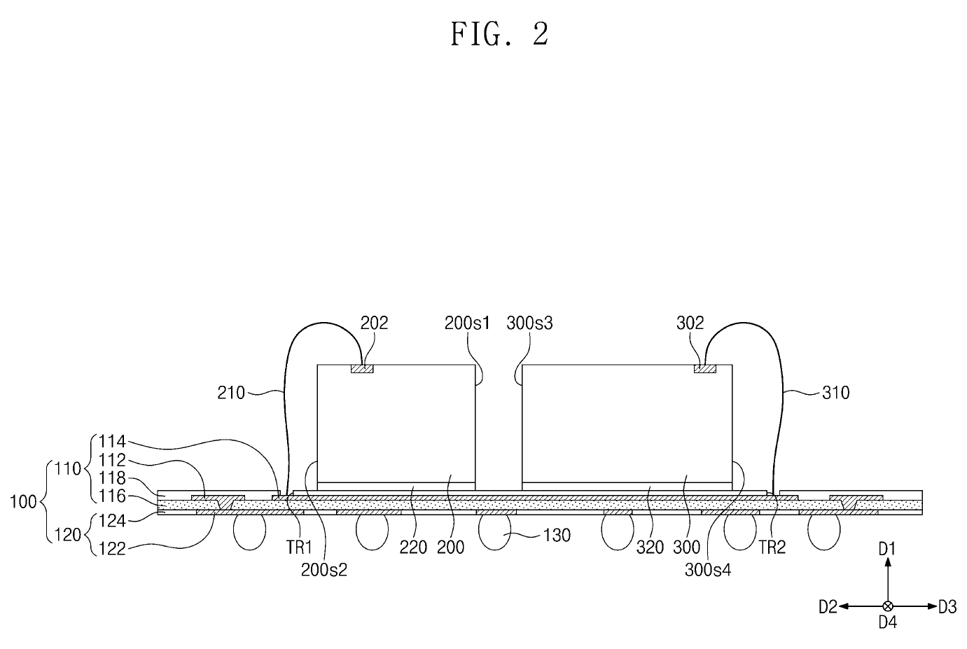

Hereinafter, a semiconductor package according to the disclosure will be described with reference to the drawings. FIG. 1 is a plan view illustrating a semiconductor package according to the disclosure. For convenience of description, FIG. 1 illustrates some components. FIG. 2 is a cross-sectional view, taken along line A-A' of FIG. 1, illustrating the semiconductor package according to some implementations. Referring to FIGS. 1 and 2, the semiconductor package according to the disclosure may include a substrate 100, a control chip 200 and a memory chip 300. The control chip 200 and the memory chip 300 may be disposed horizontally spaced apart from each other on an upper surface of the substrate 100. The semiconductor package according to the disclosure may be a multi-chip package (MCP) including other types of semiconductor chips. The semiconductor package according to the disclosure may be a system-in-chip (SIP) stacking or arranging a plurality of semiconductor chips in one package to have one independent function. Although not shown, for example, the semiconductor package according to the disclosure may further include a passive element. The passive element may be provided in plurality as needed. Except for the control chip 200 and the memory chip 300, the semiconductor package according to the disclosure may not further include an active element.

The substrate 100 may have a form of a plate. The substrate 100 may include at least two relining layers vertically stacked. For example, the substrate 100 may include an upper relining layer 110 and a lower relining layer 120. The upper relining layer 110 may be stacked on an upper surface of the lower relining layer 120. Differently describing, the substrate 100 may include the lower relining layer 120 and the upper relining layer 110 sequentially stacked in a first direction D1. The substrate 100 may have a height in the first direction D1 of about 50 µm to about 150 µm. More specifically, a height in the first direction D1 from a lower surface of the lower relining layer 120 to the upper surface of the upper relining layer 110 may be about 50 µm to about 150 µm. In some implementations, the first direction D1 may be a direction vertical to a lower surface of the substrate 100. A second direction D2 may be one direction parallel to the lower surface of the substrate 100, and vertical to the first direction D1. A third direction D3 may be a direction parallel to the lower surface of the substrate 100, and opposed to the second direction D2. A fourth direction D4 may be a direction parallel to the lower surface of the substrate 100, and vertical to the first direction D1, the second direction D2 and the third direction D3.

The upper relining layer 110 may include a first conductive pattern 112, a connection pattern 114, a first insulating pattern 116 and an upper protective layer 118. A planar shape of the first insulating pattern 116 may be a shape of a plate. The first insulating pattern 116 may include an insulating polymer or the photoimageable dielectric (PID). For example, the photoimageable dielectric (PID) may include at least one of photosensitive polyimide, polybenzoxazole (PBO), a phenol-based polymer or a benzocyclobutene-based polymer. The first conductive pattern 112 and the connection pattern 114 may be provided on the first insulating pattern 116. The first conductive pattern 112 and the connection pattern 114 may be horizontally spaced apart from each other on the first insulating pattern 116.

The first conductive pattern 112 may be exposed onto an upper surface of the first insulating pattern 116. The first conductive pattern 112 may protrude onto the first insulating pattern 116. The first conductive pattern 112 may have a damascene structure. The first conductive pattern 112 may have a shape of alphabet T. More specifically describing, the first conductive pattern 112 may have a line portion protruding onto the upper surface of the first insulating pattern 116, and a via portion extending from the line portion of the first conductive pattern 112. The line portion of the first conductive pattern 112 may extend in the second direction D2. For example, the first conductive pattern 112 may have a width in the fourth direction D4 of about 5 µm to about 90 µm. The via portion of the first conductive pattern 112 may protrude from the line portion of the first conductive pattern 112 in an opposite direction of the first direction D1. A length of the line portion of the first conductive pattern 112 in the second direction D2 may be longer than a length of the via portion in the second direction D2. The via portion may penetrate the first insulating pattern 116. The via portion may penetrate the first insulating pattern 116 to be electrically connected to the lower relining layer 120 placed thereunder. Differently describing, the via portion may be a configuration for vertically connecting the upper relining layer 110 and the lower relining layer 120. Differently describing, the line portion of the first conductive pattern 112 placed on the first insulating pattern 116 may be a head part used as a horizontal lining or pad. The via portion of the first conductive pattern 112 may be a tail part. The first conductive pattern 112 may be a configuration for horizontal relining in the upper relining layer 110. The first conductive pattern 112 may have a conductive material. For example, the first conductive pattern 112 may include copper (Cu). The first conductive pattern 112 may be provided in plurality.

It is described in FIG. 1 that the first conductive pattern 112 has a shape of alphabet T, but the disclosure is not limited thereto. For example, the first conductive pattern 112 may have a shape of alphabet T turned upside down. The line portion of the first conductive pattern 112 may be provided on a lower surface of the first insulating pattern 116. The line portion of the first conductive pattern 112 may protrude onto the lower surface of the first insulating pattern 116. The line portion of the first conductive pattern 112 may horizontally extend on the lower surface of the first insulating pattern 116. The via portion of the first conductive pattern 112 may protrude onto an upper surface of the line portion of the first conductive pattern 112. The via portion may penetrate the first insulating pattern 116 to be exposed onto an upper surface of the upper relining layer 110. In this case, upper substrate pads may be further provided on the upper surface of the first insulating pattern 116 as needed. The upper substrate pads may be in contact with the exposed upper surface of the via portion. The upper substrate pads may serve to connect elements mounted on the substrate 100 and the first conductive pattern 112. Hereinafter, description will be made on the basis of implementations of FIGS. 1 and 2.

In some implementations, the first conductive pattern 112 and the connection pattern 114 may be lining patterns in the substrate 100. The connection pattern 114 may be a connection path, that electrically connects the memory chip 300 and the control chip 200, of the relining patterns. The first conductive pattern 112 may be the other lining pattern of the lining patterns except for the connection pattern 114. The first conductive pattern 112 may be electrically connected to at least one of the control chips 200, the memory chip 300 or the passive element.

The connection pattern 114 may be provided on the first insulating pattern 116. The connection pattern 114 may be disposed horizontally spaced apart from the line portion of the first conductive pattern 112 on the first insulating pattern 116. The connection pattern 114 may protrude onto the upper surface of the first insulating pattern 116. The connection pattern 114 may horizontally extend on the first insulating pattern 116. On a plan view. the first conductive pattern 112 may have a width in the fourth direction D4 of about 5 µm to about 90 µm. The connection pattern 114 may include a conductive material. For example, the connection pattern 114 may include copper (Cu). A material that constitutes the connection pattern 114 may be the same as a material that constitutes the first conductive pattern 112. The connection pattern 114 may be provided in plurality. Some of the connection patterns 114 may have a shape similar to the first conductive pattern 112. For example, although not shown, the some of the connection patterns 114 may include a line portion and a via portion protruding from the line portion in an opposite direction of the first direction D1. The Line portion of the connection patterns 114 may be provided on the upper surface of the first insulating pattern 116. The line portion of the connection patterns 114 may be vertically spaced apart from the lower surface of the first insulating pattern 116. The other the connection patterns 114 may not include the via portion. For example, upper surfaces and lower surfaces of the other connection patterns may be flat. Differently describing, the other connection patterns may have a constant height in the first direction D1 along the second direction D2. The other connection patterns may be vertically spaced apart from the lower surface of the first insulating pattern 116.

The upper protective layer 118 covering the first insulating pattern 116 may be provided on the upper surface of the first insulating pattern 116. At least a portion of the upper surface of the first insulating pattern 116 may be in contact with the upper protective layer 118. For example, about 50% to about 70% of the upper surface of the first insulating pattern 116 may be in contact with a lower surface of the upper protective layer 118. In the semiconductor package according to implementations of the disclosure, except for the first conductive pattern 112 and the connection pattern 114, a separate metal layer may not be provided between the upper surface of the first insulating pattern 116 and the upper protective layer 118. More specifically describing, the semiconductor package according to implementations of the disclosure may not include a ground layer, having a plate shape, interposed between the upper surface of the first insulating pattern 116 and the upper protective layer 118. In some implementations, the ground layer may include a conductive material layer or an electromagnetic wave-blocking layer at least partially covering the lining patterns.

The upper protective layer 118 may cover the upper surface of the first insulating pattern 116, and may surround the first conductive pattern 112 and the connection pattern 114. The upper protective layer 118 may at least partially cover the first conductive pattern 112. The upper protective layer 118 may at least partially cover the connection pattern 114. The upper protective layer 118 may include trenches. The trenches may penetrate the upper protective layer 118. The trenches may be penetrations holes exposing a portion of the first conductive pattern 112 and a portion of the connection pattern 114 onto an upper surface of the substrate 100. The portion of the first conductive pattern 112 and the portion of the connection pattern 114 exposed through the trenches may be electrically connected to elements in the semiconductor package. A number and disposition of the trenches may be changed as needed. Hereinafter, for convenience of description, it will be described assuming that the upper protective layer 118 has a first trench TR1 and a second trench TR2.

The first and second trenches TR1 and TR2 may be provided on an upper surface of the connection pattern 114. The first and second trenches TR1 and TR2 may vertically overlap or cover the connection pattern 114. As discussed herein, vertically overlap may refer to at least a portion of a first element overlays or covers at least a portion of a second element. For example, the first and second trenches TR1 and TR2 vertically overlapping the connection pattern can refer to the first and second trenches TR1 and TR2 overlaying or covering at least a portion of the connection pattern 114. As another example, when viewed in a direction normal to the upper surface of the substrate 100 (on which the connection pattern 114 is positioned), at least a portion of the trenches TR1 and TR2 overlay or cover at least a portion of the connection pattern 114. At least a portion of the upper surface of the connection pattern 114 may be exposed onto an upper surface of the upper protective layer 118 by the first and second trenches TR1 and TR2. The portion of the connection pattern 114 exposed onto the first trench TR1 may server as an upper substrate pad for being electrically connected to the control chip 200. Differently describing, the first trench TR1 may be a penetration hole partially exposing the connection pattern 114 so as to connect the control chip 200 and the connection pattern 114. The other portion of the connection pattern 114 exposed onto the second trench TR2 may server as an upper substrate pad for being electrically connected to the memory chip 300. Differently describing, the second trench TR2 may be a penetration hole partially exposing the connection pattern 114 so as to connect the memory chip 300 and the connection pattern 114. Each of the first trench TR1 and the second trench TR2 may be provided in plurality. Specific position relationship of the first and second trenches TR1 and TR2, the control chip 200 and the memory chip 300 will be described later in more detail. The upper protective layer 118 may include an insulating material. The upper protective layer 118 may include an insulating material or a photoimageable dielectric.

The lower relining layer 120 may be provided on a lower surface of the upper relining layer 110. The lower relining layer 120 may include a second conductive pattern 122 and a lower protective layer 124. The second conductive pattern 122 may be provided on the lower surface of the first insulating pattern 116. The second conductive pattern 122 may protrude onto the lower surface of the first insulating pattern 116. The second conductive pattern 122 may horizontally extend on the lower surface of the first insulating pattern 116. An upper surface of the second conductive pattern 122 may be in contact with a lower surface of the via portion of the first conductive pattern 112. The second conductive pattern 122 may be electrically connected to the first conductive pattern 112. The second conductive pattern 122 may include a conductive material. For example, the second conductive pattern 122 may include copper (Cu). A material that constitutes the second conductive pattern 122 may be the same as a material that constitutes the first conductive pattern 112 and the connection pattern 114, but the disclosure is not limited thereto.

The lower protective layer 124 may be provided on a lower surface of the second conductive pattern 122. The lower protective layer 124 may cover the lower surface of the first insulating pattern 116, and may surround the second conductive pattern 122. A lower surface of the second conductive pattern 122 may be exposed onto a lower surface of the lower protective layer 124. The lower protective layer 124 may include an insulating material. The lower protective layer 124 may include an insulating material or a photoimageable dielectric. A material that constitutes the lower protective layer 124 may be the same as a material that constitutes the upper protective layer 118, but the disclosure is not limited thereto.

An external terminal 130 may be provided under the lower relining layer 120. The external terminal 130 may be provided on the second conductive pattern 122 provided on the lower surface of the lower relining layer 120. The exposed lower surface of the second conductive pattern 122 may be electrically connected to the external terminal 130. That is, a portion of the second conductive pattern 122 may be a lower substrate pad provided on a lower surface of the substrate 100. The external terminal 130 may include a solder ball, a solder bump or the like. Each of the second conductive pattern 122 and the external terminal 130 may be provided in plurality.

In the semiconductor package according to implementations of the disclosure, except for the second conductive pattern 122, a separate metal layer may not be provided between the lower surface of the first insulating pattern 116 and the lower protective layer 124. More specifically describing, the semiconductor package according to implementations of the disclosure may not include a ground layer, having a plate shape, interposed between the lower surface of the first insulating pattern 116 and the lower protective layer 124.

The control chip 200 and the memory chip 300 may be provided on the substrate 100. The control chip 200 and the memory chip 300 may be disposed on the substrate 100, horizontally spaced apart from each other on the upper surface of the substrate 100. For example, the control chip 200 and the memory chip 300 may be spaced apart from each other on the upper surface of the substrate 100 in the third direction D3.

The control chip 200 may be provided on an upper surface of the connection pattern 114. The control chip 200 may overlap or cover at least a portion of the connection pattern 114 in the first direction D1. A lower surface of the control chip 200 may overlap or cover the connection pattern 114. The control chip 200 may include a first side surface 200s1 and a second side surface 200s2. The first side surface 200s1 of the control chip 200 may be a side surface nearest to the memory chip 300 of side surfaces of the control chip 200 parallel to each other in the first direction D1. The second side surface 200s2 of the control chip 200 may oppose the first side surface 200s1. Differently describing, the second side surface 200s2 of the control chip 200 may be a side surface farthest from the memory chip 300 in the second direction D2 of the side surfaces of the control chip 200 parallel to each other in the first direction D1. For example, the connection pattern 114 may overlap all of the first side surface 200s1 and the second side surface 200s2. The connection pattern 114 overlapping all of the first side surface 200s1 and the second side surface 200s2 can refer to at least a portion of the connection pattern 114 extending beyond or crossing the planes of each of the first side surface 200s1 and the second side surface 200s2. As some examples, the portions of the connection pattern 114 crossing or extending beyond the planes of each of the first side surface 200s1 and the second side surface 200s2 may not be covered by the control chip 200. Although not shown, the control chip 200 may include an integrated circuit. For example, the control chip 200 may be a logic chip including a logic circuit. The logic chip may be a controller that controls the memory chip 300. The semiconductor chip may be a processor such as an ASIC as a host such as a CPU, a GPU and a SoC. The control chip 200 may include a control chip pad 202 provided on an upper surface of the control chip 200. The control chip pad 202 may be a pad connected to the integrated circuit. The control chip pad 202 may be exposed onto the upper surface of the control chip 200.

The control chip 200 may be electrically connected to the substrate 100. The control chip 200 may be electrically connected to the connection pattern 114 by a control chip wire 210. The control chip wire 210 may extend from an upper surface of the control chip pad 202 to be connected to the upper surface of the connection pattern 114 exposed by the first trench TR1. For example, on a plan view, the first trench TR1 may be disposed spaced apart from the first side surface 200s1 of the control chip 200 in the second direction D2. The control chip wire 210 may be spaced apart from the first side surface 200s1 of the control chip 200 in the second direction D2. The control chip wire 210 may extend from an upper surface of the control chip 200 to the outside of the first side surface 200s1 of the control chip 200. The control chip wire 210 may be connected to one end of the connection pattern 114 on the first side surface 200s1 of the control chip 200. On a plan view, the first trench TR1 may not be provided between the control chip 200 and the memory chip 300. Differently describing, the upper protective layer 118 may cover an upper surface of the connection pattern 114 between the control chip 200 and the memory chip 300. More preferably, the upper protective layer 118 may cover all of the upper surface of the connection pattern 114 between the control chip 200 and the memory chip 300. The control chip wire 210 may not be connected to the connection pattern 114 between the control chip 200 and the memory chip 300. Accordingly, the control chip wire 210 may not protrude onto the first side surface 200s1 of the control chip 200. The control chip wire 210 may not be interposed between the first side surface 200s1 of the control chip 200 and a third side surface 300s3 of the memory chip 300. The control chip wire 210 may include metal such as gold (Au). The substrate 100 may be electrically connected to the integrated circuit of the control chip 200 through the control chip wire 210 and the control chip pad 202. The control chip wire 210 and the control chip pad 202 may be provided in plurality. Disposition of the control chip wire 210, the control chip pad 202 and the first trench TR1 may be changed as needed.

The control chip 200 may be attached onto the substrate 100 by using a first adhesive layer 220. The first adhesive layer 220 may include a die attach film (DAF) or a non-conductive film (NCF). The first adhesive layer 220 may fill a space between the substrate 100 and the control chip 200, covering the lower surface of the control chip 200.

The memory chip 300 may be provided on the substrate 100. The memory chip 300 may be provided on an upper surface of the connection pattern 114. The memory chip 300 may overlap or cover at least a portion of the connection pattern 114 in the first direction D1. A lower surface of the memory chip 300 and a lower surface of the control chip 200 may overlap or cover the connection pattern 114. The connection pattern 114 may overlap the lower surface of the control chip 200 and the lower surface of the memory chip 300. As an example, when viewed in a direction normal to the lower surface of the substrate 100 (the connection pattern 114, the control chip 200 and the memory chip 300 being positioned over the upper surface of the substrate 100), at least a portion of the connection pattern 114 may cover or overlay at least a portion of each of the lower surfaces of the control chip 200 and the memory chip 300. The memory chip 300 may be disposed, on the upper surface of the substrate 100, spaced apart from the control chip 200 in the third direction D3. The memory chip 300 may include the third side surface 300s3 and a fourth side surface 300s4. The third side surface 300s3 of the memory chip 300 may be a side surface facing the first side surface 200s1 of the control chip 200. Differently describing, the third side surface 300s3 of the memory chip 300 may be a side surface nearest to the control chip 200 of side surfaces of the memory chip 300 parallel to each other in the first direction D1. The fourth side surface 300s4 of the memory chip 300 may oppose the third side surface 300s3. Differently describing, the fourth side surface 300s4 of the memory chip 300 may be a side surface farthest from the control chip 200 in the third direction D3 of the side surfaces of the memory chip 300 parallel to each other in the first direction D1. The control chip 200 and the memory chip 300 may be near to each other. For example, a distance from the first side surface 200s1 of the control chip 200 to the third side surface 300s3 of the memory chip 300 in the third direction D3 may be about 100 µm to about 300 µm.

Although not shown, the memory chip 300 may include an integrated circuit. For example, the memory chip 300 may be a non-volatile memory element including a memory circuit. The memory chip 300 may be a NAND flash memory (hereinafter, a NAND) having storage ability in high-capacity and at a high-speed. Alternatively, the memory chip 300 may be a phase-change random access memory (PRAM), a magnetic random access memory (MRAM), a resistive random access memory (ReRAM), a ferromagnetic random access memory (FRAM), a NOR flash memory or the like. The memory chip 300 may include a memory chip pad 302 provided on an upper surface of the memory chip 300. The memory chip pad 302 may be a pad connected to the integrated circuit. The memory chip pad 302 may be exposed onto the upper surface of the memory chip 300. The memory chip 300 may be electrically connected to the substrate 100.

The memory chip 300 may be electrically connected to the connection pattern 114 by a memory chip wire 310. The memory chip wire 310 may extend from an upper surface of the memory chip pad 302 to be connected to the upper surface of the connection pattern 114 exposed by the second trench TR2. One end of the memory chip wire 310 may be in contact with the upper surface of the memory chip pad 302. The other end of the memory chip wire 310 may be in contact with the upper surface of the connection pattern 114 exposed by the second trench TR2. On a plan view, the second trench TR2 may be disposed spaced apart from the fourth side surface 300s4 of the memory chip 300 in the third direction D3. The memory chip wire 310 may be spaced apart from the fourth side surface 300s4 of the memory chip 300 in the third direction D3. The memory chip wire 310 may extend from an upper surface of the memory chip 300 to the outside of the fourth side surface 300s4 of the memory chip 300. The control chip wire 210 may be connected to the other end of the connection pattern 114 on the third side surface 300s4 of the memory chip 300. On a plan view, the second trench TR2 may not be provided between the control chip 200 and the memory chip 300. Differently describing, the upper protective layer 118 may cover an upper surface of the connection pattern 114 between the control chip 200 and the memory chip 300. More preferably, the upper protective layer 118 may cover all of the upper surface of the connection pattern 114 between the control chip 200 and the memory chip 300. The memory chip wire 310 may not be connected to the connection pattern 114 between the control chip 200 and the memory chip 300. Accordingly, the memory chip wire 310 may not protrude onto the third side surface 300s3 of the memory chip 300. The memory chip wire 310 may include metal such as gold (Au). The substrate 100 may be electrically connected to the integrated circuit of the memory chip 300 through the memory chip wire 310 and the memory chip pad 302. The control chip 200 and the memory chip 300 may be electrically connected to each other through the control chip wire 210, the connection pattern 114, and the memory chip wire 310. The memory chip wire 310 and the memory chip pad 302 may be provided in plurality. Disposition of the memory chip wire 310, the memory chip pad 302 and the second trench TR2 may be changed as needed.

The memory chip 300 may be attached onto the substrate 100 by using a second adhesive layer 320. The second adhesive layer 320 may include a die attach film (DAF) or a non-conductive film (NCF). The second adhesive layer 320 may fill a space between the substrate 100 and the memory chip 300, covering the lower surface of the memory chip 300.

The connection pattern 114 may cross the first side surface 200s1 and the second side surface 200s2 of the control chip 200, and the third side surface 300s3 and the fourth side surface 300s4 of the memory chip 300. On a plan view, the connection pattern 114 may pass all of both side surfaces 200s1 and 200s2 of the control chip 200, and both side surfaces 300s3 and 300s4 of the memory chip 300. The control chip 200 and the memory chip 300 may cover most of the connection pattern 114. The most of the connection pattern 114 may be disposed under the lower surface of the control chip 200 and the lower surface of the memory chip 300. The most of the connection pattern 114 may be vertically overlapped or covered by the control chip 200 and the memory chip 300. For example, about 70% to about 95% of a planar area of the connection pattern 114 may be vertically overlapped or covered by the control chip 200 and the memory chip 300. More preferably, about 85% to about 95% of the planar area of the connection pattern 114 may be vertically overlapped or covered by the control chip 200 and the memory chip 300. In this case, the planar area of the connection pattern 114 may be an area of the upper surface of the connection pattern 114 seen on a plan view or in a direction normal to the upper surface of the substrate 100.

The control chip 200 and the memory chip 300 may absorb an electric field and/or a magnetic field occurring inside or outside the semiconductor package to block electromagnetic interference (EMI). More specifically, the most of the connection pattern 114 may be overlapped or covered by the control chip 200 and the memory chip 300 to reduce a noise occurring in an electrical signal transmitted along the connection pattern 114. That is, the semiconductor package with improved electrical characteristics may be provided. When a distance between the control chip 200 and the memory chip 300 is great, a length of a connection path electrically connecting the control chip 200 and the memory chip 300 may increase. In addition, most of the connection path may be exposed to an electromagnetic wave. The semiconductor package according to implementations of the disclosure may not need a separate ground layer for preventing introduction of an electric field and/or a magnetic field through the exposed connection path. Accordingly, the semiconductor package with a small size may be provided.

It is described in FIGS. 1 and 2 that the connection pattern 114 crosses all of the first side surface 200s1 and the second side surface 200s2 of the control chip 200, and the third side surface 300s3 and the fourth side surface 400s4 of the memory chip 300, but the disclosure is not limited thereto. For example, the connection pattern 114 may cross the first side surface 200s1 of the control chip 200 and the third side surface 300s3 of the memory chip 300. As discussed herein, crossing a surface (e.g., crossing the first side surface 200s) can refer to crossing a plane of the surface. The plane of the surface can refer to the plane in which the surface lies or the plane that is coplanar with the surface. Thus, the connection pattern 114 can cross a plane of each of the first side surface 200s1 and the second side surface 200s2 of the control chip 200, and each of the third side surface 300s3 and the fourth side surface 400s4 of the memory chip 300.

For example, a planar shape of the connection pattern may have a shape of alphabet L accurately rotated 180° clockwise. On a plan view, one end of the connection pattern may be disposed protruding onto one side surface connecting the first side surface 200s1 and the second side surface 200s2. The other end of the connection pattern may be disposed protruding from the fourth side surface 400s4 in the third direction D3. In this case, although not shown, the first trench TR1 may be disposed outside the one side surface of the first trench TR1. The control chip wire 210 may extend from an upper surface of the control chip pad 202 to be connected to the upper surface of the connection pattern 114 exposed through the first trench TR1. The second trench TR2 may be disposed spaced apart from the fourth side surface 400s4 in the third direction D3. The memory chip wire 310 may extend from an upper surface of the memory chip pad 302 to be connected to the upper surface of the connection pattern 114 exposed through the second trench TR2.

As described above, the planar shape and disposition of the connection pattern 114 may be changed as needed. In this case, the connection pattern 114 may cross the first side surface 200s1 of the control chip 200 and the third side surface 300s3 of the memory chip 300. As described with reference to FIGS. 1 and 2, the control chip wire 210 and the memory chip wire 310 may not be interposed between the first side surface 200s1 and the third side surface 300s3.

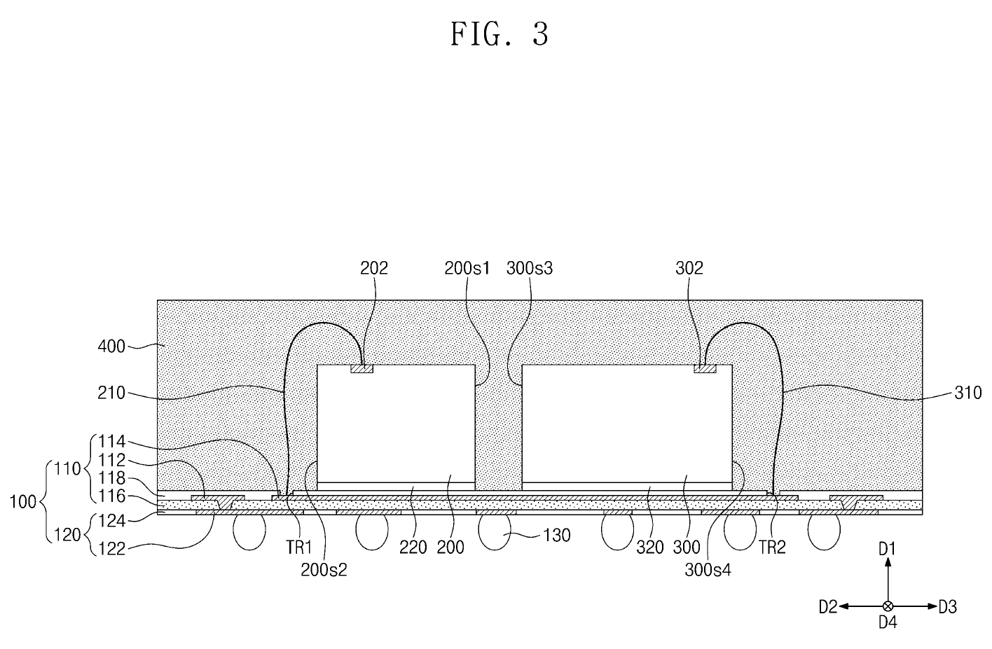

FIG. 3 is a cross-sectional view of a semiconductor package according to implementations of the disclosure. Except for what is described below, duplicate description of that made above will be omitted. Referring to FIG. 3, a molding layer 400 may be provided on an upper surface of the substrate 100. The molding layer 400 may cover the control chip 200 and the memory chip 300. The molding layer 400 may surround the control chip wire 210 and the memory chip wire 310. An upper surface of the molding layer 400 may have a higher level than an uppermost end of the control chip wire 210 protruding onto an upper surface of the control chip 200. An upper surface of the molding layer 400 may have a higher level than an uppermost end of the memory chip wire 310 protruding onto an upper surface of the memory chip 300. The molding layer 400 may include an insulating polymer material. For example, the molding film 400 may include an epoxy molding compound (EMC).

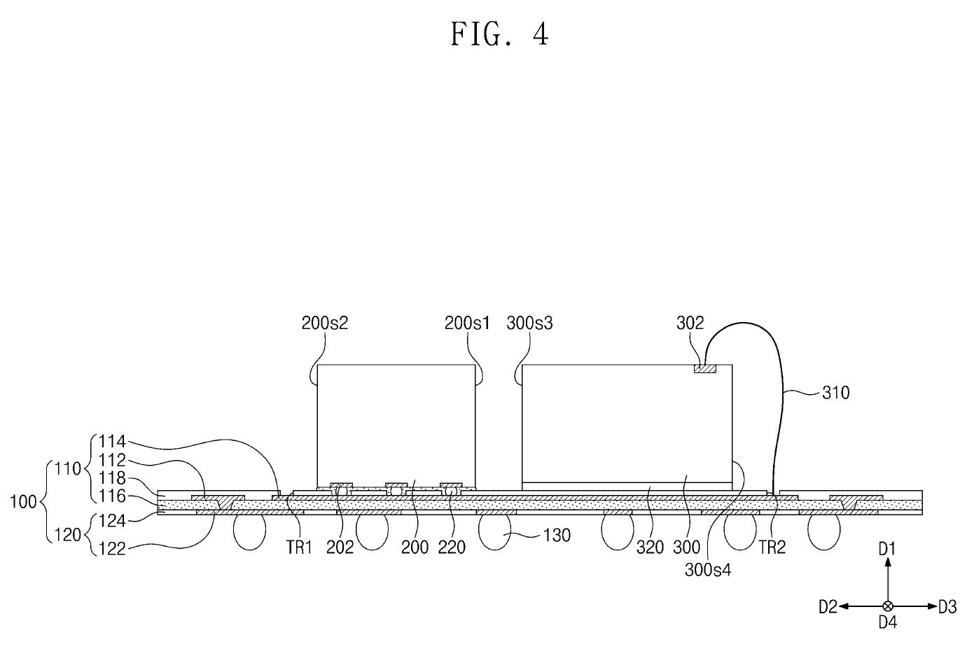

FIG. 4 is a cross-sectional view of a semiconductor package according to implementations of the disclosure. Except what is described below, duplicate description of that made above will be omitted. It is described in FIG. 2 that the control chip 200 is electrically connected to the substrate 100 through the control chip wire 210, but the disclosure is not limited thereto. Referring to FIG. 4, unlike FIG. 2, the control chip wire 210 may not be provided. In addition, the control chip pad 202 may be provided on a lower surface of the control chip 200. As described with reference to FIGS. 1 and 2, the control chip pad 202 may be connected to an integrated circuit of the control chip 200. A lower surface of the control chip pad 202 may be exposed onto the lower surface of the control chip 200. Alternatively, the control chip pad 202 may protrude onto the lower surface of the control chip 200. A control chip connection terminal 204 may be provided on the control chip pad 202. The control chip connection terminal 204 may include a solder ball or a solder bump.

The first trench TR1 of the upper protective layer 118 of the substrate 100 may be provided on the lower surface of the control chip 200. The control chip connection terminal 204 may be disposed on the first trench TR1. One end of the control chip connection terminal 204 may be connected to the control chip pad 202. The other end of the control chip connection terminal 204 may be connected to the exposed connection pattern 114 through the first trench TR1. Differently describing, the control chip connection terminal 204 may electrically connect the control chip pad 202 and the connection pattern 114. The control chip 200 may be mounted on the substrate 100 by using the control chip connection terminal 204. That is, the control chip 200 may be mounted on the Substrate 100 in a flip chip bonding manner. The control chip pad 202, the control chip connection terminal 204 and the first trench TR1 may be provided in plurality.

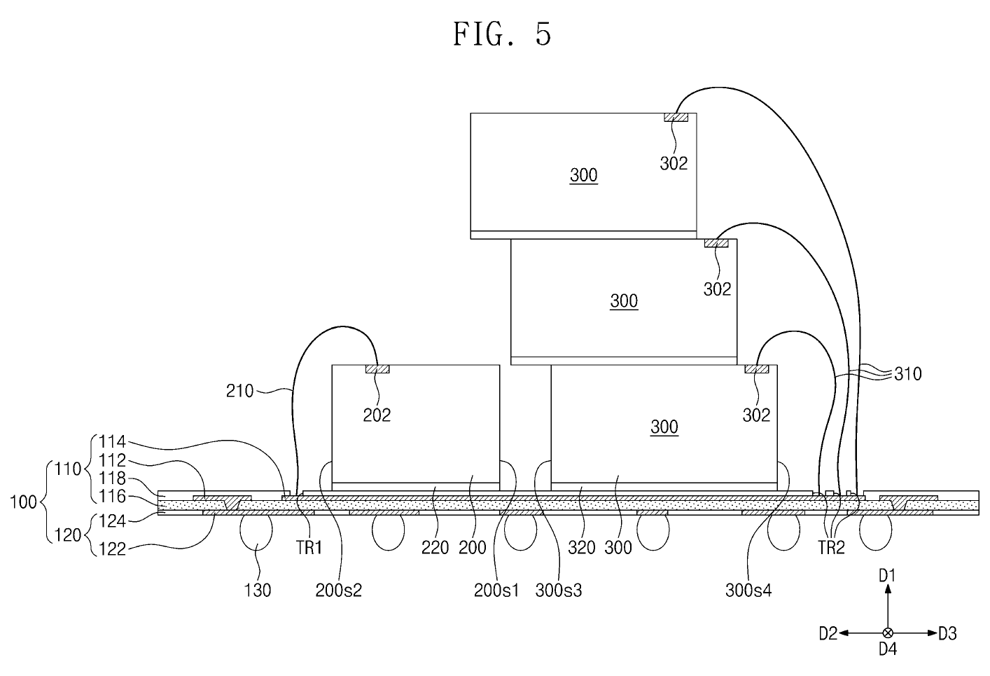

FIG. 5 is a cross-sectional view of a semiconductor package according to implementations of the disclosure. Except for what is described below, duplicate description of that made above will be omitted. Referring to FIG. 5, unlike FIG. 2, the memory chip 300 may be provided in plurality. The memory chips 300 may be stacked on the substrate 100. For example, the memory chips 300 may be offset stacked in the second direction D2. At least a portion of each of the memory chips 300 may vertically overlap or cover at least a portion of a memory chip thereunder. The other portion of each of the memory chips 300 may protrude onto the third side surface 300s3 of the memory chip thereunder. Differently describing, the memory chips 300 may be stacked in a step way on an upper surface of the substrate 100 along the second direction D2. The memory chip 300 may be stacked inclined in the second direction D2, which may be an upward-sloping step form (i.e., a cascade form). A distance from the first side surface 200s1 of the control chip 200 to the third side surface 300s3 of the lowermost memory chip 300 in the third direction D3 may be about 100 µm to about 300 µm. It is illustrated in FIG. 5 that three memory chips 300 are stacked, but the disclosure is not limited thereto, and a number of stacked memory chips 300 may be changed as needed.

Each of the memory chips 300 may include the memory chip pad 302 provided on an upper surface thereof. The memory chip pad 302 of each of the memory chips 300 may not overlap or cover the memory chip 300 thereon. The memory chip pad 302 of each of the memory chips 300 may be spaced apart from the memory chip 300 thereon in the third direction D3. Each of the memory chips 300 may include the memory chip wire 310 extending from the memory chip pad 302 to the substrate 100.

In this case, the substrate 100 may include a plurality of second trenches TR2. Each of the second trenches TR2 may be a penetration hole partially exposing the connection pattern 114 such that the connection pattern 114 and the memory chip wire 310 of the memory chip 300 corresponding thereto are connected to each other. For example, the second trenches TR2 may be spaced apart from the fourth side surface 300s4 of the memory chips 300 in the third direction D3. The second trenches TR2 may be disposed spaced apart from each other on the substrate 100. Each of the memory chip wires 310 may extend from the memory chip pad 302 to be connected to the connection pattern 114 exposed by the second trench TR2. The second adhesive layer 320 covering a lower surface of each of the memory chips 300 may be provided. The memory chips 300 may be attached to the substrate 100 or the memory chip 300 thereunder by using the second adhesive layer 320.

At least a portion of an uppermost memory chip 300 of the memory chips 300 may vertically overlap or cover at least a portion of the control chip 200. More specifically describing, a partial region of the uppermost memory chip 300 adjacent to the third side surface 300s3 may overlap or cover a partial region of the control chip 200 adjacent to the first side surface 200s1.

It is illustrated in FIG. 5 that a height of the control chip 200 in the first direction D1 is similar to a height of each of the memory chips 300 in the first direction D1, but the disclosure is not limited thereto. For example, the height of the control chip 200 in the first direction D1 may be smaller than the height of the memory chip 300 in the first direction D1.

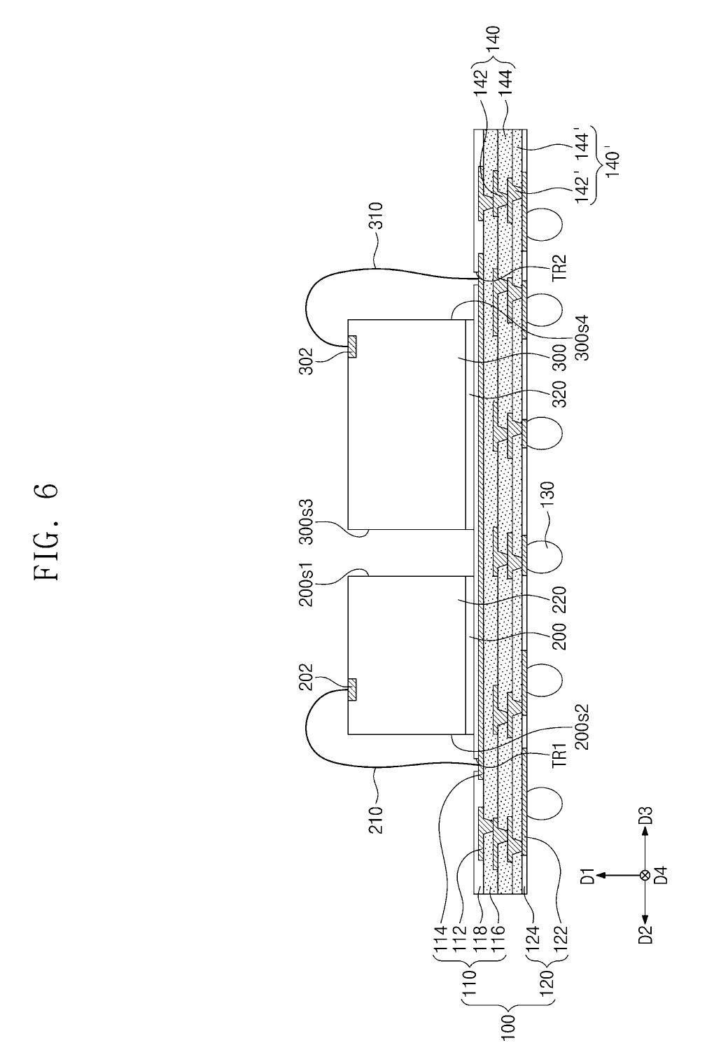

FIG. 6 is a cross-sectional view of a semiconductor package according to implementations of the disclosure. Except for what is described below, duplicate description of that made above will be omitted. Referring to FIG. 6, unlike FIG. 2, the substrate 100 may further include a central relining layer 140 provided between the lower relining layer 120 and the upper relining layer 110. The central relining layer 140 may be provided in plurality as needed. For example, two central relining layers 140 may be provided between the upper relining layer 110 and the lower relining layer 120. Each of the central relining layers 140 may include a third conductive pattern 142 and a second insulating pattern 144.

The second insulating pattern 144 may include an insulating polymer or a photoimageable dielectric (PID). For example, the photoimageable dielectric may include at least one of photosensitive polyimide, polybenzoxazole (PBO), a phenol-based polymer or a benzocyclobutene-based polymer. A material that constitutes the second insulating pattern 144 may be the same as a material that constitutes the first insulating pattern 116.

The third conductive pattern 142 may be provided on the second insulating pattern 144. The third conductive pattern 142 may be exposed onto an upper surface of the second insulating pattern 144. The third conductive pattern 142 may protrude onto the second insulating pattern 144. The third conductive pattern 142 may have a damascene structure. The third conductive pattern 142 may have a shape of alphabet T. More specifically describing, as the first conductive pattern 112, the third conductive pattern 142 may have a line portion protruding onto the upper surface of the second insulating pattern 144, and a via portion extending from the line portion of the third conductive pattern 142. A planar shape of the line portion of the third conductive pattern 142 may extend in a direction parallel to the upper surface of the substrate 100. For example, the third conductive pattern 142 may have a width in the fourth direction D4 of about 5 µm to about 90 µm.

The via portion may protrude from the line portion of the third conductive pattern 142 in an opposite direction of the first direction D1. A length of the line portion of the third conductive pattern 142 in the second direction D2 may be longer than a length of the via portion in the second direction D2. The via portion may penetrate the second insulating pattern 144. The via portion may penetrate the second insulating pattern 144 to be electrically connected to the relining layer placed thereunder. Differently describing, the via may be a configuration for vertically connecting adjacent relining layers. The third conductive pattern 142 may be a configuration for horizontal relining in the central relining layer 140. The third conductive pattern 142 may include a conductive material. For example, the third conductive pattern 142 may include copper (Cu). A material that constitutes the third insulating pattern 142 may be the same as a material that constitutes the first and second conductive patterns 112 and 122. The third conductive pattern 142 may be provided in plurality.

Hereinafter, for convenience of description, it is described assuming that two central relining layers 140 are provided between the upper relining layer 110 and the lower relining layer 120. In addition, of the two central relining layers, a central relining layer adjacent to the upper relining layer 110 will be referred to as a first central relining layer 140, and a central relining layer adjacent to the lower relining layer 120 will be referred to as a second central relining layer 140`. However, the first central relining layer 140 and the second central relining layer 140` may be distinguished on the basis of positions thereof for convenience of description, and types and configuration of the central relining layers 140 and 140` may be substantially the same as each other.

The third conductive pattern 142 of the first central relining layer 140 may be electrically connected to the first conductive pattern 112 or the connection pattern 114. For example, the Line portion of the third conductive pattern 142 may be in contact with a lower surface of the via portion of the first conductive pattern 112. A line portion of a third conductive pattern 142` of the second central relining layer 140` may be in contact with the via portion of the third conductive pattern 142. A via portion of the third conductive pattern 142` of the second central relining layer 140` may be in contact with an upper surface of the second conductive pattern 142. The third conductive patterns 142 and 142` may electrically connect the first conductive pattern 112 and the second conductive pattern 122. The first conductive pattern 112 and the connection pattern 114 may be electrically connected to the outside of the substrate 100 through the third conductive patterns 142 and 142` and the second conductive pattern 122.

Except for the third conductive patterns 142 and 142`, the central relining layers 140 and 140' may not include a metal layer. For example, the central relining layers 140 and 140` may not include a ground layer having a form of a planar plate covering second insulating patterns 144 and 144`. More specifically describing, the upper surface of the second insulating pattern 144 exposed onto the third conductive pattern 142 may be in contact with a lower surface of the first insulating pattern 116. The upper surface of the second insulating pattern 144` exposed onto the third conductive pattern 142` of the second central relining layer 140` may be in contact with the second insulating pattern 144 of the first central relining layer 140.

In the semiconductor package according to implementations of the disclosure, most of the connection pattern 114 may be overlapped or covered by the control chip 200 and the memory chip 300. The control chip 200 and the memory chip 300 may block an electromagnetic wave introduced to the connection pattern 114. Accordingly, the substrate 100 may not include a separate ground layer that blocks the electromagnetic wave, and the semiconductor package with a small size may be provided. In addition, since a ground layer having a form of a wide planar plate is not included, an economically efficient semiconductor package may be provided.

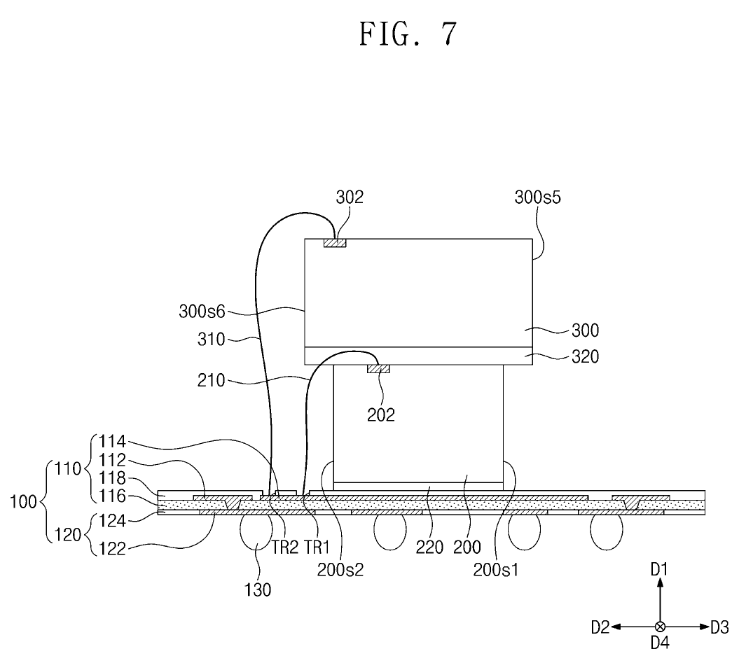

FIG. 7 is a cross-sectional view of a semiconductor package according to implementations of the disclosure. Except for what is described below, duplicate description of that made above will be omitted. Referring to FIG. 7, unlike FIG. 2, the memory chip 300 may be stacked on the control chip 200. The memory chip 300 may be provided on an upper surface of the control chip 200. The memory chip 300 may be attached onto the upper surface of the control chip 200 by the second adhesive layer 320 on a lower surface of the memory chip 300. The second adhesive layer 320 may partially surround the control chip wire 210 protruding onto the upper surface of the control chip 200. Differently describing, the second adhesive layer 320 may fill a space between the control chip 200 and the memory chip 300, and may cover an uppermost end of the control chip wire 210 protruding onto the upper surface of the control chip 200. The lower surface of the memory chip 300 may be spaced apart from the control chip wire 210 of the control chip 200 by the second adhesive layer 320.

The memory chip 300 may include a fifth side surface 300s5 and a sixth side surface 300s6. The fifth side surface 300s5 of the memory chip 300 may be a side surface parallel to the first side surface 200s1 of the control chip 200 of the side surfaces of the memory chip 300 parallel to each other in the first direction D1. In this case, unlike what is described with reference to FIGS. 1 and 2, the first side surface 200s1 of the control chip 200 may be any one arbitrary side surface of the side surfaces of the control chip 200 parallel to each other in the first direction D1. The second side surface 200s2 of the control chip 200 may oppose the first side surface 200s1. The sixth side surface 300s6 of the memory chip 300 may oppose the fifth side surface 300s5.

The control chip 200 may include the control chip pad 202. For example, the control chip pad 202 may be provided in one region adjacent to the second side surface 200s2 of the control chip 200. The first trench TR1 of the upper protective layer 118 may be provided spaced apart from the second side surface 200s2 of the control chip 200 in the second direction D2. The control chip wire 210 may extend from the control chip pad 202 to be connected to the upper surface of the connection pattern 114 exposed by the first trench TR1.

The memory chip 300 may include the memory chip pad 302. For example, the memory chip pad 302 may be provided in one region adjacent to the sixth side surface 300s6 of the memory chip 300. The memory chip wire 310 may extend from the memory chip pad 302 to be connected to the connection pattern 114. For example, on a plan view, the second trench TR2 of the upper protective layer 118 may be provided spaced apart from the sixth side surface 300s6 of the memory chip 300 in the second direction D2. The memory chip wire 310 may extend from the memory chip pad 302 to be connected to the upper surface of the connection pattern 114 exposed by the second trench TR2.

It is illustrated in FIG. 7 that the second trench TR2 is spaced apart from the first trench TR1 in the second direction D2, but the disclosure is not limited thereto. Disposition of the memory chip pad 302, the memory chip wire 310 and the second trench TR2 may be changed as needed.

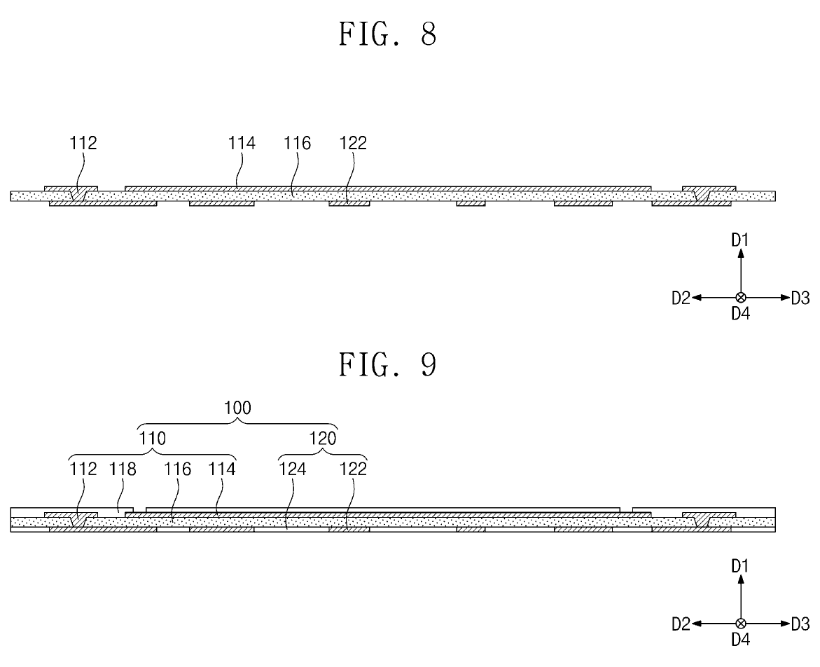

FIGS. 8 to 9 are cross-sectional views for describing a method for manufacturing a semiconductor package according to implementations of the disclosure. Referring to FIG. 8, the first insulating pattern 116 may be formed. A conductive layer may be formed on the first insulating pattern 116, and then the second conductive pattern 122 may be formed by patterning the conductive layer. Thereafter, the result may be turned over. For example, the second conductive pattern 122 may be provided so as to be placed on the lower surface of the first insulating pattern 116. A conductive layer may be formed on the first insulating pattern 116, and then the first conductive pattern 112 and the connection pattern 114 may be formed by patterning the conductive layer. In this case, the first conductive pattern 112 and the connection pattern 114 may be the same as what is described with reference to FIGS. 1 and 2. For example, the first conductive pattern 112 may have a line portion and a via portion extending from the line portion. The connection pattern 114 may be disposed horizontally spaced apart from the first conductive pattern 112 on the first insulating pattern 116. The connection pattern 114 may extend in a direction parallel to the upper surface of the first insulating pattern 116. On a plan view, the connection pattern 114 may have a width of about 5 µm to about 90 µm. The first conductive pattern 112, the connection pattern 114 and the second conductive pattern 122 may be lining patterns of the substrate 100 (see FIG. 2). The connection pattern 114 may be a lining pattern to be described later, that electrically connects the memory chip 300 and the control chip 200, of the relining patterns.

Referring to FIG. 9, the upper protective layer 118 covering the first conductive pattern 112 and the connection pattern 114 may be formed on the upper surface of the first insulating pattern 116. The first trench TR1 and the second trench TR2 may be formed by patterning the upper protective layer 118. The connection pattern 114 may be at least partially exposed onto the first trench TR1 and the second trench TR2. The first trench TR1 and the second trench TR2 may be the same as what is described with reference to FIGS. 1 and 2. The first trench TR1 may be a penetration hole partially exposing the connection pattern 114 so as to connect the control chip 200 and the connection pattern 114. The second trench TR2 may be a penetration hole partially exposing the connection pattern 114 so as to connect the memory chip 300 and the connection pattern 114. The lower protective layer 124 covering the second conductive pattern 122 may be formed on the lower surface of the first insulating pattern 116. The lower protective layer 124 may be patterned so that at least a portion of the second conductive pattern 122 may be exposed onto the lower protective layer 124. The at least a portion of the second conductive pattern 122 exposed onto the lower protective layer 124 may be a lower substrate pad of the substrate 100. As described above, the substrate 100 including the upper relining layer 110 and the lower relining layer 120 vertically stacked may be manufactured.

Referring to FIG. 2 again, the control chip 200 and the memory chip 300 may be mounted on the substrate 100. The control chip 200 and the memory chip 300 may be the same as what is described with reference to FIGS. 1 and 2. The control chip 200 and the memory chip 300 may be disposed horizontally spaced apart from each other on the upper surface of the substrate 100. A distance between the control chip 200 and the memory chip 300 may be about 100 µm to about 300 µm. The control chip 200 and the memory chip 300 may be disposed on the upper surface of the substrate 100 so as to overlap or cover the connection pattern 114. For example, about 70% to about 95% of a planar area of the connection pattern 114 may be overlapped or covered by the control chip 200 and the memory chip 300. The control chip 200 may be fixed on the substrate 100 by the first adhesive layer 220. The control chip 200 may be fixed on the upper surface of the substrate 100 by attaching the first adhesive layer 220 to the lower surface of the control chip 200, and to the upper surface of the substrate 100. The memory chip 300 may be fixed on the substrate 100 by the second adhesive layer 320. The memory chip 300 may be fixed on the upper surface of the substrate 100 by attaching the second adhesive layer 320 to the lower surface of the memory chip 300, and to the upper surface of the substrate 100.

The control chip wire 210 may be formed between the substrate 100 and the upper surface of the control chip 200. The control chip wire 210 may extend from the control chip pad 202 of the control chip 200 to the connection pattern 114 of the substrate 100 exposed by the first trench TR1, and may be formed. The control chip wire 210 may include a metal material such as gold (Au). The control chip pad 202 of the control chip 200 may be electrically connected to the substrate 100 through the control chip wire 210. That is, the control chip 200 may be mounted on the substrate 100 in a wire bonding manner.

The memory chip wire 310 may be formed between the substrate 100 and the upper surface of the memory chip 300. The memory chip wire 310 may extend from the memory chip pad 302 of the memory chip 300 to the connection pattern 114 of the substrate 100 exposed by the second trench TR2, and may be formed. The memory chip wire 310 may include a metal material such as gold (Au). The memory chip pad 302 of the memory chip 300 may be electrically connected to the substrate 100 through the memory chip wire 310. That is, the memory chip 300 may be mounted on the substrate 100 in a wire bonding manner. As described above, the semiconductor package of FIGS. 1 and 2 may be manufactured.

Alternatively, referring to FIG. 5 again, the memory chip 300 may be provided in plurality. The memory chip 300 may be stacked on the upper surface of the substrate 100 in a step way. The memory chips 300 may be offset stacked in the second direction D2. A distance from the first side surface 200s1 of the control chip 200 to the third side surface 300s3 of the lowermost memory chip 300 in the third direction D3 may be about 100 µm to about 300 µm. The control chip 200 and the memory chips 300 may be disposed on the upper surface of the substrate 100 so as to overlap or cover the connection pattern 114. For example, about 70% to about 95% of a planar area of the connection pattern 114 may be overlapped or covered by the control chip 200 and the memory chips 300. The memory chips 300 may be attached to the substrate 100 or the memory chip 300 thereunder by using the second adhesive layer 320. At least a portion of an uppermost memory chip 300 of the memory chips 300 may vertically overlap or cover at least a portion of the control chip 200.

The control chip wire 210 may be formed between the substrate 100 and the upper surface of the control chip 200. The control chip wire 210 may extend from the control chip pad 202 of the control chip 200 to the connection pattern 114 of the substrate 100 exposed by the first trench TR1, and may be formed. The memory chip wires 310 may be formed between the substrate 100 and the upper surfaces of the memory chips 300. The memory chip wires 310 may extend from the memory chip pad 302 of each of the memory chips 300 to the connection pattern 114 of the substrate 100 exposed by the second trench TR2, and may be formed. Disposition of the first trench TR1 and the second trench TR2 may be the same as what is described with reference to FIG. 5. For example, the substrate 100 may include a plurality of second trenches TR2. As described above, the semiconductor package of FIG. 5 may be manufactured.

Alternatively, referring to FIG. 7 again, the control chip 200 and the memory chip 300 may be mounted on the substrate 100. The memory chip 300 may be stacked on the control chip 200 on the upper surface of the substrate 100. The control chip 200 and the memory chip 300 may be disposed on the upper surface of the substrate 100 so as to overlap or cover the connection pattern 114. For example, about 70% to about 95% of a planar area of the connection pattern 114 may be overlapped or covered by the control chip 200 and the memory chip 300. The control chip 200 may be fixed on the substrate 100 by the first adhesive layer 220. The memory chip 300 may be fixed on the substrate 100 by the second adhesive layer 320.

The control chip wire 210 may be formed between the substrate 100 and the upper surface of the control chip 200. The control chip wire 210 may extend from the control chip pad 202 of the control chip 200 to the connection pattern 114 of the substrate 100 exposed by the first trench TR1, and may be formed. The memory chip wire 310 may be formed between the substrate 100 and the upper surface of the memory chip 300. The memory chip wire 310 may extend from the memory chip pad 302 of the memory chip 300 to the connection pattern 114 of the substrate 100 exposed by the second trench TR2, and may be formed. Disposition of the first trench TR1 and the second trench TR2 may be the same as what is described with reference to FIG. 7. As described above, the semiconductor package of FIG. 7 may be manufactured.

In a semiconductor package according to implementations of the disclosure, most of a connection pattern of a substrate may be overlapped or covered by semiconductor chips mounted on the substrate. The semiconductor chips may reduce a noise of an electrical signal by blocking an electromagnetic wave on the connection pattern. Accordingly, the semiconductor package with improved electrical characteristics may be provided.

In addition, in the semiconductor package according to implementations of the disclosure, a distance between the semiconductor chips mounted on the substrate may be smaller. Accordingly, the semiconductor package with a small size may be provided.

In an implementation of the disclosure, a method for manufacturing a semiconductor package includes forming a substrate by stacking at least two relining layers, and mounting a control chip and a memory chip on an upper surface of the substrate, wherein an uppermost relining layer of the relining layers includes a connection pattern connecting the control chip and the memory chip, and about 70% to about 95% of a planar area of the connection pattern vertically overlaps the control chip and the memory chip.

In one or more implementations, the memory chip may be horizontally spaced apart from the control chip on the upper surface of the substrate, and a distance between the control chip and the memory chip may be about 100 m to about 300 m.

In one or more implementations, the memory chip may be stacked on an upper surface of the control chip on the upper surface of the substrate.

In one or more implementations, the memory chip may be provided in plurality, the memory chips may be stacked in a step form on the upper surface of the substrate, and at least a portion of an uppermost memory chip of the memory chips overlaps a portion of an upper surface of the control chip.

In one or more implementations, the connection pattern may extend in a direction parallel to the upper surface of the substrate, and on a plan view, the connection pattern may have a width of about 5 m to about 90 m.

Although the implementations of the present invention have been described, it is understood that the present invention should not be limited to these implementations but various changes and modifications can be made by one ordinary skilled in the art within the spirit and scope of the present invention as hereinafter claimed. Therefore, it should be understood that the implementations described above are exemplary in all respects and are not intended to be limiting.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor package comprising:
a substrate; and
a control chip and a memory chip on an upper surface of the substrate,
wherein the substrate comprises:
an insulating pattern; and
a connection pattern on an upper surface of the insulating pattern,
wherein the connection pattern electrically connects the control chip and the memory chip, and
wherein at least a portion of the connection pattern is covered by a lower surface of the control chip and a lower surface of the memory chip.

2. The semiconductor package of claim 1, comprising
a memory chip wire connecting the memory chip and the substrate,
wherein the substrate comprises an upper protective layer covering the upper surface of the insulating pattern,
wherein the upper protective layer partially exposes an upper surface of the connection pattern, and
wherein an exposed upper surface of the connection pattern is partially in contact with the memory chip wire.

3. The semiconductor package of claim 2, wherein between the control chip and the memory chip, the upper protective layer covers the upper surface of the connection pattern.

4. The semiconductor package of claim 2, wherein the substrate comprises:
a conductive pattern horizontally spaced apart from the connection pattern on the insulating pattern; and
a lower substrate pad on a lower surface of the insulating pattern,
wherein the conductive pattern comprises a line portion and a via portion that extends from the line portion into the insulating pattern,
wherein an upper surface of the lower substrate pad is in contact with a lower surface of the via portion of the conductive pattern, and
wherein a lower surface of the lower substrate pad is exposed onto the substrate.

5. The semiconductor package of claim 1, wherein the connection pattern extends in a direction parallel to the upper surface of the substrate and has a width of 5 µm to 90 µm.

6. The semiconductor package of claim 1, wherein 70% to 95% of a planar area of the connection pattern is covered by the control chip and the memory chip.

7. The semiconductor package of claim 1, wherein the memory chip is horizontally spaced apart from the control chip on the upper surface of the substrate,
wherein the control chip comprises a first side surface,
wherein the memory chip comprises a second side surface facing the first side surface, and
wherein a distance between the first side surface and the second side surface is 100 µm to 300 µm.

8. The semiconductor package of claim 1, wherein the memory chip is horizontally spaced apart from the control chip on the upper surface of the substrate,
wherein the semiconductor package comprises a plurality of memory chips, the plurality of memory chips comprising the memory chip,
wherein the plurality of memory chips are stacked in a step form on the upper surface of the substrate, and
wherein at least a portion of an uppermost memory chip of the plurality of memory chips covers a portion of an upper surface of the control chip.

9. The semiconductor package of claim 1, wherein the memory chip is on an upper surface of the control chip.

10. A semiconductor package comprising:
a substrate comprising at least two relining layers;
a control chip on an upper surface of the substrate; and
a memory chip horizontally spaced apart from the control chip on the upper surface of the substrate,
wherein an uppermost relining layer of the at least two relining layers comprises:
an insulating pattern; and
a connection pattern on an upper surface of the insulating pattern,
wherein the control chip comprises a first side surface and a second side surface opposed to each other,
wherein the memory chip comprises a third side surface and a fourth side surface opposed to each other,
wherein the connection pattern connects the control chip and the memory chip, and
wherein the connection pattern crosses a plane of the first side surface, a plane of the second side surface, a plane of the third side surface and a plane of the fourth side surface.

11. The semiconductor package of claim 10, wherein the uppermost relining layer comprises a conductive pattern horizontally spaced apart from the connection pattern on the insulating pattern,
wherein the conductive pattern comprises a line portion and a via portion extending from the line portion to extend into the insulating pattern,
wherein a lowermost relining layer of the at least two relining layers comprises a lower substrate pad,
wherein a lower surface of the lower substrate pad is exposed onto a lower surface of the substrate, and
wherein an upper surface of the lower substrate pad is in contact with a lower surface of the via portion of the conductive pattern.

12. The semiconductor package of claim 11, wherein the substrate has a height of 50 µm to 150 µm.

13. The semiconductor package of claim 10, wherein the first side surface faces the third side surface, and
wherein a distance from the first side surface to the third side surface is 100 µm to 300 µm.

14. The semiconductor package of claim 13, wherein 70% to 95% of a planar area of the connection pattern is covered by the control chip and the memory chip.

15. The semiconductor package of claim 10, comprising a plurality of memory chips, wherein the plurality of memory chips comprises the memory chip,
wherein the plurality of memory chips are stacked in a step-wise manner on the upper surface of the substrate, and
wherein at least a portion of an uppermost memory chip of the plurality of memory chips covers a portion of an upper surface of the control chip.

16. The semiconductor package of claim 10, wherein the control chip comprises a control chip pad on an upper surface of the control chip, and a control chip wire extending from the control chip pad to be connected to the connection pattern,
wherein the memory chip comprises a memory chip pad on an upper surface of the memory chip, and a memory chip wire extending from the memory chip pad to be connected to the connection pattern, and
wherein the control chip and the memory chip are electrically connected to each other through the control chip wire, the memory chip wire and the connection pattern.

17. A semiconductor package comprising:
a substrate comprising at least two relining layers that are vertically stacked;
a control chip on an upper surface of the substrate;
a memory chip horizontally spaced apart from the control chip on the upper surface of the substrate;
an external connection terminal on a lower surface of the substrate;
a control chip wire connecting the control chip and the substrate; and
a memory chip wire connecting the memory chip and the substrate,
wherein an uppermost relining layer of the at least two relining layers comprises:
an insulating pattern; and
a connection pattern electrically connecting the control chip and the memory chip on an upper surface of the insulating pattern,
wherein the control chip comprises a first side surface and a second side surface opposite to and facing away from the first side surface,
wherein the memory chip comprises a third side surface facing the first side surface and a fourth side surface opposite to and facing away from the third side surface,
wherein the control chip wire is connected to a first end of the connection pattern on the second side surface, wherein the memory chip wire is connected to a second end of the connection pattern on the fourth side surface, and
wherein the connection pattern extends between the first end of the connection pattern and the second end of the connection pattern.

18. The semiconductor package of claim 17, wherein a distance between the first side surface and the third side surface is about 100 µm to about 300 µm.

19. The semiconductor package of claim 17, wherein 70% to 95% of a planar area of the connection pattern is covered by the control chip and the memory chip.

20. The semiconductor package of claim 17, comprising a molding layer covering the control chip and the memory chip on the upper surface of the substrate.
